(19) United States
(12) Patent Application Publication
(10) Pub. No.: US 2025/0275201 A1
(43) Pub. Date: Aug. 28, 2025

(54) SEMICONDUCTOR DEVICE

(71) Applicant: Samsung Electronics Co., Ltd., Suwon-si (KR)

(72) Inventors: Woosuk CHOI, Suwon-si (KR); Beomjin PARK, Suwon-si (KR); Changwoo NOH, Suwon-si (KR); Myung Gil KANG, Suwon-si (KR); Dongwon KIM, Suwon-si (KR)

(73) Assignee: Samsung Electronics Co., Ltd., Suwon-si (KR)

(21) Appl. No.: 18/936,324

(22) Filed: Nov. 4, 2024

(30) Foreign Application Priority Data
Feb. 28, 2024 (KR) 10-2024-0029011

(51) Int. Cl. H01L 29/08; H01L 29/06; H01L 29/423; H01L 29/775; H01L 29/786

(52) U.S. Cl. CPC H10D 62/151; H10D 30/43; H10D 30/6735; H10D 30/6757; H10D 62/10; H10D 62/121

(57) ABSTRACT

A semiconductor device may include a substrate, source/drain patterns on the substrate, the source/drain patterns comprising a first pattern and a second pattern, the first and second patterns being spaced apart from each other, a channel pattern between the first pattern and the second pattern, the channel pattern comprising a first semiconductor pattern, a second semiconductor pattern, and a third semiconductor pattern, the first, second, and third semiconductor patterns being stacked to be spaced apart from each other, an interlayer insulating layer on the source/drain patterns, an active contact penetrating the interlayer insulating layer and in contact with the second pattern, and a backside contact penetrating the substrate and in contact with the first pattern.

### CROSS-REFERENCE TO RELATED APPLICATIONS

This U.S. non-provisional patent application claims priority under 35 U.S.C. § 119 to Korean Patent Application No. 10-2024-0029011, filed on Feb. 28, 2024, in the Korean Intellectual Property Office, the entire contents of which are hereby incorporated by reference.

### BACKGROUND OF THE INVENTION

Various example embodiments relate to a semiconductor device, and in particular, to a semiconductor device including a field effect transistor.

A semiconductor device includes an integrated circuit consisting of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high-performance semiconductor devices.

### SUMMARY

Various example embodiments of the inventive concepts provide a semiconductor device with improved electrical characteristics.

Various example embodiments of the inventive concepts provide a semiconductor device with improved reliability.

According to various example embodiments of the inventive concepts, a semiconductor device may include a substrate, source/drain patterns on the substrate, the source/drain patterns comprising a first pattern and a second pattern, the first and second patterns being spaced apart from each other, a channel pattern between the first pattern and the second pattern, the channel pattern comprising a first semiconductor pattern, a second semiconductor pattern, and a third semiconductor pattern, the first, second, and third semiconductor patterns being stacked to be spaced apart from each other, an interlayer insulating layer on the source/drain patterns, an active contact penetrating the interlayer insulating layer and in contact with the second pattern, and a backside contact penetrating the substrate and in contact with the first pattern. The first pattern has a first doping concentration, and the first doping concentration decreases as a vertical distance from the substrate in an upward direction increases, the upward direction being a direction perpendicular to an upper surface of the substrate.

According to various example embodiments of the inventive concepts, a semiconductor device may include a substrate, a power delivery network layer on a bottom surface of the substrate, source/drain patterns on the substrate, and backside contacts provided to penetrate the substrate and to electrically connect each of the source/drain patterns to the power delivery network layer. The backside contacts comprise a first backside contact and a second backside contact, the first and second backside contacts being spaced apart from each other, each of the first and second backside contacts comprises a first portion and a second portion on the first portion. A width of the first portion decreases as a vertical distance from the substrate in an upward direction increases, the upward direction being a direction perpendicular to an upper surface of the substrate, and as the vertical distance from the substrate in the upward direction increases, a width of the second portion is maintained at a constant value and then decreased.

According to various example embodiments of the inventive concepts, a semiconductor device may include a substrate including an insulating layer and an active pattern, a power delivery network layer on a bottom surface of the insulating layer, source/drain patterns on the insulating layer, the source/drain patterns comprising a first pattern and a second pattern, the first and second pattern being spaced apart from each other, a channel pattern on a side surface of the source/drain pattern, the channel pattern comprising a plurality of semiconductor patterns, the plurality of semiconductor patterns being stacked to be spaced apart from each other and include a first semiconductor pattern, a second semiconductor pattern, and a third semiconductor pattern, a gate electrode between the semiconductor patterns, the gate electrode comprising a first inner electrode, a second inner electrode, and a third inner electrode, the first, second and third inner electrodes being interposed between adjacent ones of the semiconductor patterns, and an outer electrode on the uppermost one of the semiconductor patterns, a gate insulating pattern on the gate electrode, a gate capping pattern on a top surface of the outer electrode, a first interlayer insulating layer on the source/drain patterns, a second interlayer insulating layer on the first interlayer insulating layer and the gate capping pattern, a third interlayer insulating layer on the second interlayer insulating layer, metal patterns and vias are within the third interlayer insulating layer, an active contact penetrating the first and second interlayer insulating layers and electrically connecting the second pattern of the source/drain pattern to the metal pattern, and a backside contact penetrating the insulating layer of the substrate and electrically connecting the first pattern of the source/drain pattern to the power delivery network layer. The first pattern has a first doping concentration, the second pattern has a second doping concentration, and the first doping concentration of a portion of the first pattern being adjacent to a side surface of the first semiconductor pattern, is higher than the second doping concentration of a portion of the second pattern being adjacent to the side surface of the first semiconductor pattern.

### BRIEF DESCRIPTION OF THE DRAWINGS

FIG. 1 is a plan view illustrating a semiconductor device according to various example embodiments of the inventive concepts.

FIGS. 2A to 2E are sectional views, which are respectively taken along lines A-A′, B-B′, C-C′, D-D′, and E-E′ of FIG. 1.

FIG. 3 is a graph showing dopant concentrations of first and second patterns according to a depth of a source/drain pattern of FIG. 2A.

FIGS. 4A to 4C are sectional views illustrating another example embodiment of the semiconductor device of FIG. 2A.

FIGS. 5A to 13C are diagrams illustrating a method of fabricating a semiconductor device according to various example embodiments of the inventive concepts.

### DETAILED DESCRIPTION

Various example embodiments of the inventive concepts will now be described more fully with reference to the accompanying drawings, in which example embodiments are shown.

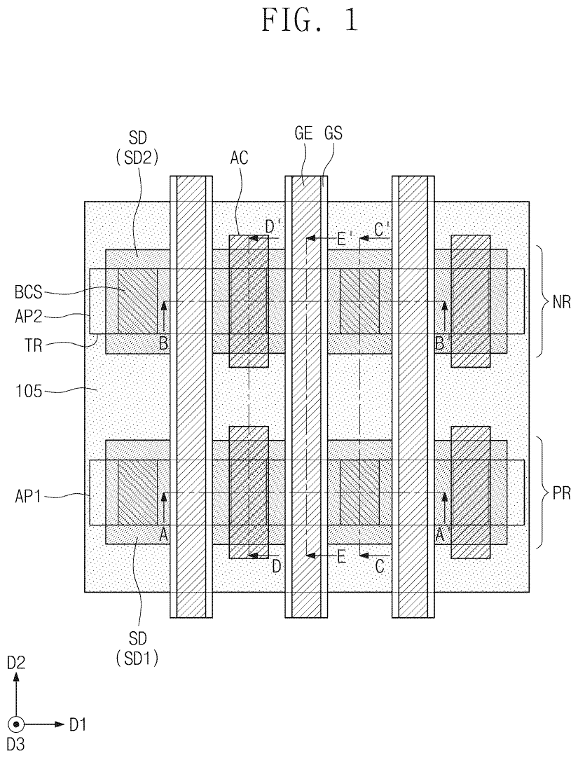

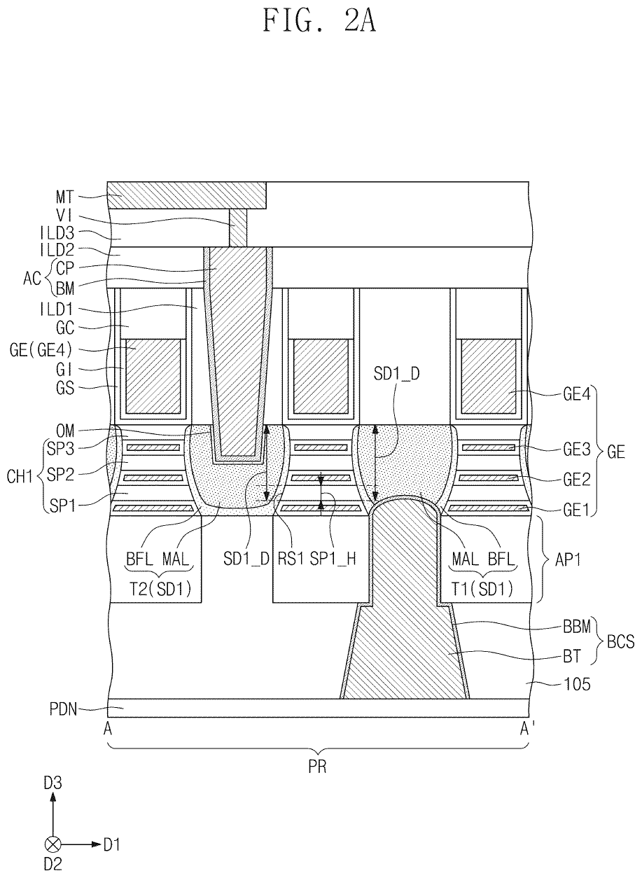

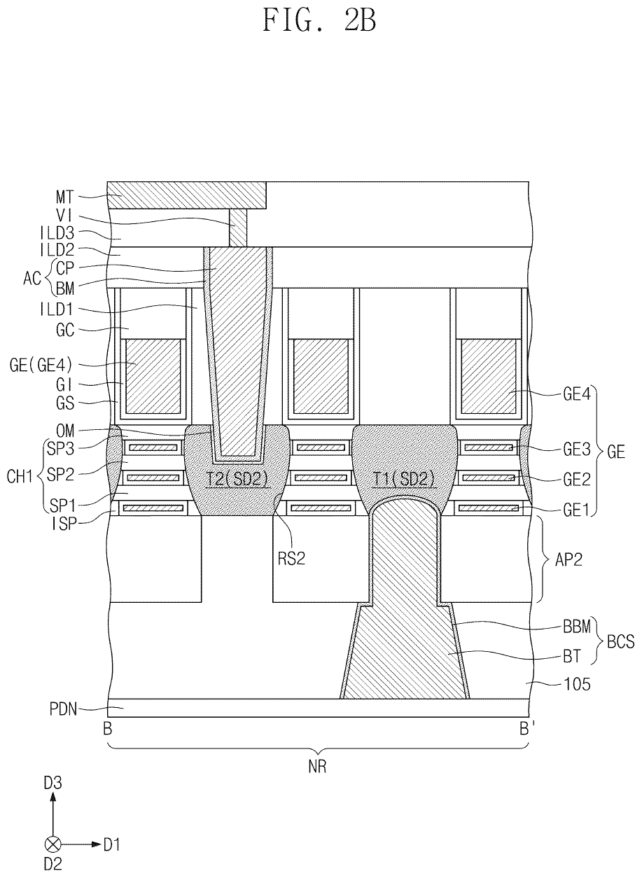

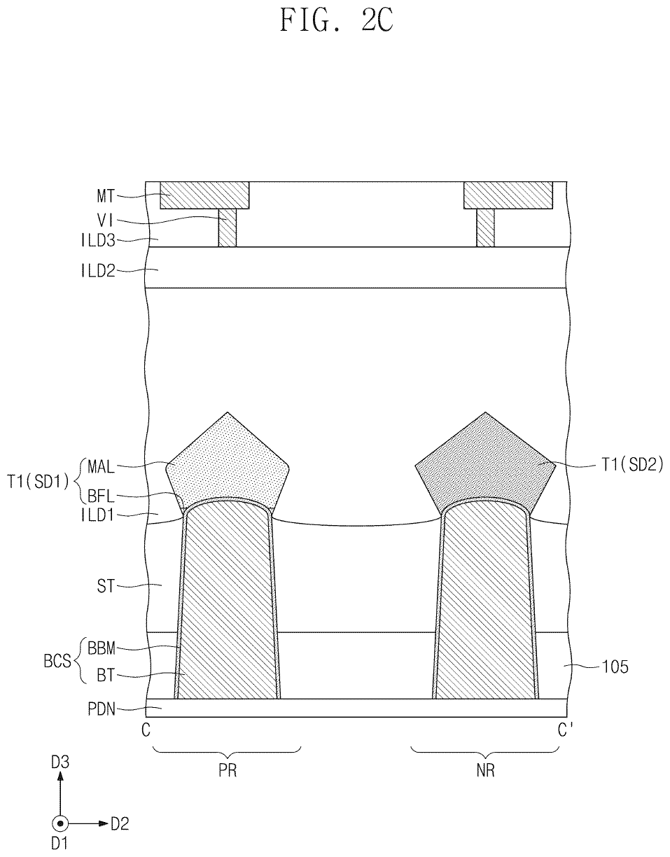

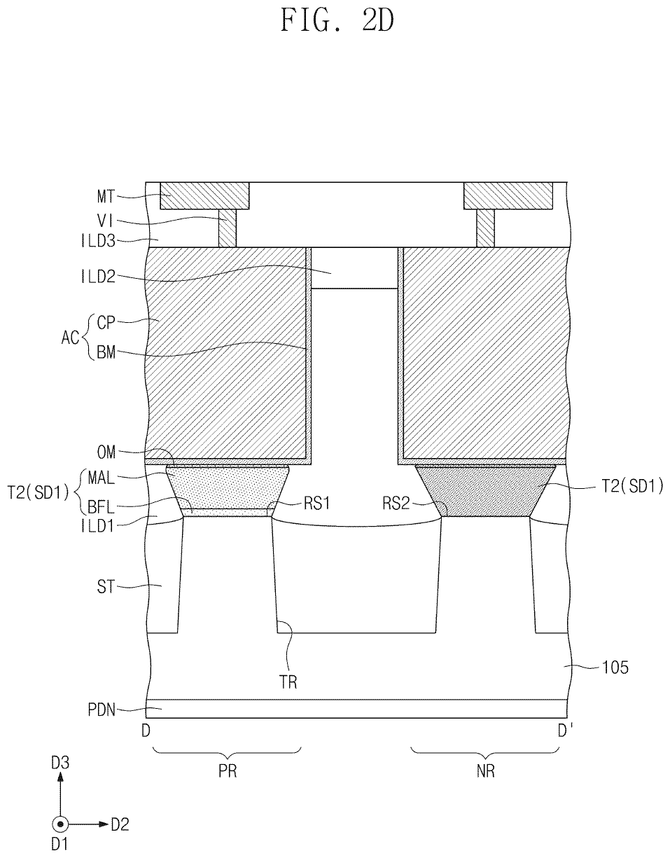

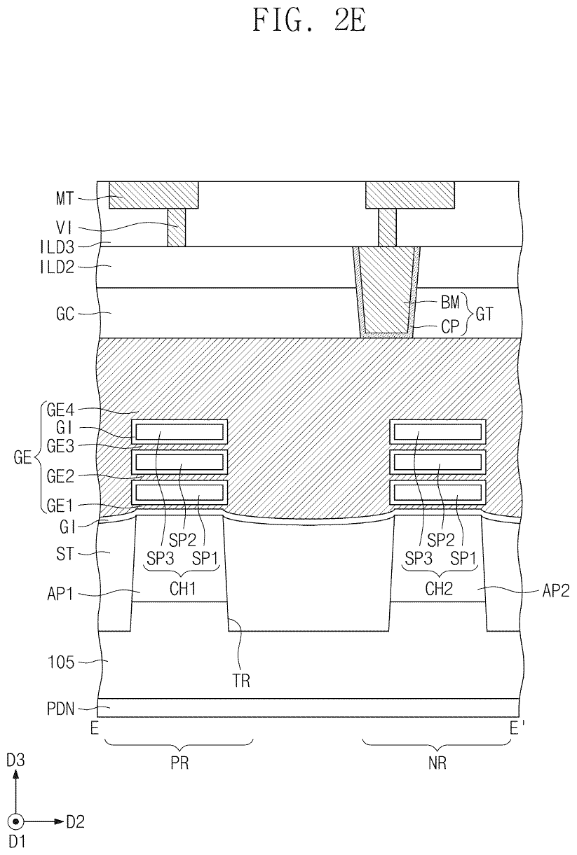

FIG. 1 is a plan view illustrating a semiconductor device according to various example embodiments of the inventive concepts. FIGS. 2A to 2E are sectional views, which are respectively taken along lines A-A′, B-B′, C-C′, D-D′, and E-E′ of FIG. 1.

Referring to FIG. 1 and FIGS. 2A to 2E, a substrate 105 including a PMOSFET region PR and an NMOSFET region NR may be provided. In various example embodiments, the substrate 105 may include a silicon-based insulating layer. That is, the substrate 105 may be an insulating substrate. For example, the substrate 105 may include at least one of silicon oxide (SiO₂), silicon nitride (SiN), or silicon oxynitride (SiON). However, example embodiments are not limited thereto. A first active pattern AP1 and a second active pattern AP2 may be provided on the substrate 105. The first active pattern AP1 may be provided on the PMOSFET region PR, and the second active pattern AP2 may be provided on the NMOSFET region NR.

In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

The PMOSFET and NMOSFET regions PR and NR may be extended in a first direction D1 and may be spaced apart from each other in a second direction D2. The first and second directions D1 and D2 may be parallel to a bottom surface of the substrate 105 and may be non-parallel (e.g., orthogonal) to each other.

The first and second active patterns AP1 and AP2 may be defined by a trench TR of the substrate 105. When viewed in a sectional view, the first and second active patterns AP1 and AP2 may be provided on protruding portions of the substrate 105. In various example embodiments, the first and second active patterns AP1 and AP2 may protrude in a third direction D3. The third direction D3 may be perpendicular to the bottom surface of the substrate 105.

A device isolation pattern ST may be provided between the first and second active patterns AP1 and AP2 to fill the trench TR. The device isolation pattern ST may enclose the first and second active patterns AP1 and AP2. The device isolation pattern ST may include an insulating material. In various example embodiments, the device isolation pattern ST may be formed of or include silicon oxide (SiO₂).

A first channel pattern CH1 may be provided on the first active pattern AP1 in the PMOSFET region PR, and a second channel pattern CH2 may be provided on the second active pattern AP2 in the NMOSFET region NR. In various example embodiments, a plurality of first channel patterns CH1 may be provided to be spaced apart from each other in the first direction D1. In various example embodiments, a plurality of second channel patterns CH2 may be provided to be spaced apart from each other in the first direction D1. Each of the first and second channel patterns CH1 and CH2 may include a first semiconductor pattern SP1, a second semiconductor pattern SP2, and a third semiconductor pattern SP3, which are adjacent to each other in the third direction D3, but the inventive concepts are not limited to this example. In various example embodiments, each of the first and second channel patterns CH1 and CH2 may include four or more semiconductor patterns. In various example embodiments, each of the first to third semiconductor patterns SP1, SP2, and SP3 may be formed of or include crystalline silicon. As an example, each of the first to third semiconductor patterns SP1, SP2, and SP3 may be formed of or include single-crystalline silicon. In various example embodiments, the first to third semiconductor patterns SP1, SP2, and SP3 may be nanosheets that are stacked.

First recesses RS1, which will be described below, may be defined between the first channel patterns CH1, which are adjacent to each other in the first direction D1. Second recesses RS2, which will be described below, may be defined between the second channel patterns CH2, which are adjacent to each other in the first direction D1.

A first source/drain pattern SD1 may be provided on the PMOSFET region PR of the substrate 105, and a second source/drain pattern SD2 may be provided on the NMOSFET region NR of the substrate 105. That is, the first source/drain pattern SD1 and the second source/drain pattern SD2 may be provided on protruding portions, which are extended from the substrate 105 in the third direction D3. The first source/drain pattern SD1 may be provided to fill the first recess RS1, and the second source/drain pattern SD2 may be provided to fill the second recess RS2. Each of the first and second source/drain patterns SD1 and SD2 may be electrically connected to the first to third semiconductor patterns SP1, SP2, and SP3. The first source/drain patterns SD1 may be impurity regions of a first conductivity type (e.g., p-type), and the second source/drain patterns SD2 may be impurity regions of a second conductivity type (e.g., n-type). A pair of the first source/drain patterns SD1 may be electrically connected to each other through the first channel pattern CH1. A pair of the second source/drain patterns SD2 may be electrically connected to each other through the second channel pattern CH2.

The first source/drain patterns SD1 may be formed of or include a semiconductor material (e.g., SiGe) whose lattice constant is greater than that of the first channel pattern CH1. In this case, the pair of the first source/drain patterns SD1 may exert a compressive stress on the first channel pattern CH1 therebetween. The second source/drain patterns SD2 may be formed of or include the same semiconductor element (e.g., Si) as the second channel pattern CH2.

The first source/drain pattern SD1 may include a buffer layer BFL covering an inner surface of the first recess RS1 and a main layer MAL filling most of a remaining portion of the first recess RS1. In various example embodiments, each of the buffer layer BFL and the main layer MAL may be formed of or include silicon-germanium (SiGe). The buffer layer BFL may contain a relatively low concentration of germanium (Ge). The main layer MAL may contain a relatively high concentration of germanium (Ge). In various example embodiments, the buffer layer BFL may contain only silicon (Si).

The first and second source/drain patterns SD1 and SD2 may include a first pattern T1, which is electrically connected to a power delivery network layer PDN to be described below, and a second pattern T2, which is electrically connected to an active contact AC to be described below.

A gate electrode GE may be provided on the first and second channel patterns CH1 and CH2 to cross the first and second channel patterns CH1 and CH2. In various example embodiments, a plurality of gate electrodes GE may be provided. The gate electrodes GE may be extended in the second direction D2 and may be spaced apart from each other in the first direction D1.

The gate electrode GE may include inner electrodes GE1-GE3 and an outer electrode GE4. The inner electrodes GE1-GE3 of the gate electrode GE may be provided between the semiconductor patterns SP1, SP2, and SP3 and the active patterns AP1 or AP2. The outer electrode GE4 of the gate electrode GE may be provided on the uppermost one of the semiconductor patterns SP1, SP2, and SP3. As an example, the inner electrodes GE1-GE3 of the gate electrode GE may include a first inner electrode GE1, a second inner electrode GE2, and a third inner electrode GE3, but the inventive concepts are not limited to this example. In various example embodiments, the inner electrodes of the gate electrode GE may include four or more inner electrodes. In detail, the first inner electrode GE1 may be interposed between the active patterns AP1 or AP2 and the first semiconductor pattern SP1. The second inner electrode GE2 may be interposed between the first semiconductor pattern SP1 and the second semiconductor pattern SP2. The third inner electrode GE3 may be interposed between the second semiconductor pattern SP2 and the third semiconductor pattern SP3. The outer electrode GE4 of the gate electrode GE may be provided on the third semiconductor pattern SP3.

The gate electrode GE may include a first metal pattern and a second metal pattern on the first metal pattern. The first metal pattern may include a work-function metal, which can be used to adjust a threshold voltage of the transistor. The first metal pattern may be formed of or include at least one of metallic materials (e.g., Ti, Mo, W, Cu, Al, Ta, Ru, Ir, and Co) or metal nitride materials (e.g., nitride materials of Ti, Mo, W, Cu, Al, Ta, Ru, Ir, and Co). However, example embodiments are not limited thereto. In various example embodiments, the first metal pattern may further include carbon (C). The first metal pattern may be formed of or include at least one of metallic materials having different work functions.

In various example embodiments, the second metal pattern may be formed of or include at least one of metallic materials (e.g., Ti, Mo, W, Cu, Al, Ta, Ru, Ir, and Co) whose electric resistances are lower than that of the first metal pattern. However, example embodiments are not limited thereto.

The first to third inner electrodes GE1, GE2, and GE3 of the gate electrode GE may include the first metal pattern. In various example embodiments, the outer electrode GE4 of the gate electrode GE may include the first metal pattern and the second metal pattern.

A gate capping pattern GC may be provided on a top surface of the gate electrode GE. In detail, the gate capping pattern GC may be provided on the outer electrode GE4 of the gate electrode GE. In various example embodiments, the gate capping pattern GC may be formed of or include at least one of SiON, SiCN, SiOCN, or SiN. However, example embodiments are not limited thereto.

Gate spacers GS may be provided on side surfaces of the outer electrode GE4 of the gate electrode GE and may be extended to side surfaces of the gate capping pattern GC. The gate spacer GS may include a single layer or a composite layer. In various example embodiments, the gate spacer GS may be formed of or include at least one of SiON, SiCN, SiOCN, or SiN. However, example embodiments are not limited thereto.

A gate insulating pattern GI may be interposed between the gate electrode GE and the first to third semiconductor patterns SP1, SP2, and SP3. The gate insulating pattern GI may cover a top surface, a bottom surface, and opposite side surfaces of each of the first to third semiconductor patterns SP1, SP2, and SP3. The gate insulating pattern GI may cover a top surface of the device isolation pattern ST below the gate electrode GE. The gate insulating pattern GI may be interposed between the outer electrode GE4 and the gate spacer GS. The gate insulating pattern GI may be formed of or include at least one of silicon oxide (SiO₂), silicon oxynitride (SiON), or high-k dielectric materials. However, example embodiments are not limited thereto. In the present specification, the high-k dielectric material may be defined as a material having a dielectric constant higher than that of silicon oxide.

An inner spacer ISP may be interposed between a side surface of the second source/drain pattern SD2 and a side surface of the gate electrode GE. The inner spacer ISP may be interposed between the first to third inner electrodes GE1-GE3 and the second source/drain pattern SD2. In various example embodiments, the inner spacer ISP may include an insulating material.

A first interlayer insulating layer ILD1 may be provided on the substrate 105. The first interlayer insulating layer ILD1 may cover the gate spacers GS and the first and second source/drain patterns SD1 and SD2. A top surface of the first interlayer insulating layer ILD1 may be located at substantially the same level as a top surface of the gate capping pattern GC and a top surface of the gate spacer GS.

A second interlayer insulating layer ILD2 may be provided on the first interlayer insulating layer ILD1 to cover the gate capping pattern GC. A third interlayer insulating layer ILD3 may be provided on the second interlayer insulating layer ILD2. In various example embodiments, the first to third interlayer insulating layers ILD1, ILD2, and ILD3 may be formed of or include silicon oxide (SiO₂).

The active contact AC may penetrate the first and second interlayer insulating layers ILD1 and ILD2 in the third direction D3. In various example embodiments, a plurality of active contacts AC may be provided, and a lower portion of each of the active contacts AC may be buried in an upper portion of the second pattern T2 of the source/drain pattern SD1 or SD2. That is, the active contact AC may be a contact, which is formed through a frontside surface of the substrate 105.

A bottom surface of the active contact AC may be placed between top and bottom surfaces of the second semiconductor pattern SP2. The bottom surface of the active contact AC may be located at a level that is higher than a top surface of a backside contact BCS, which will be described below, in the third direction D3.

The active contact AC may include a conductive pattern CP penetrating the first and second interlayer insulating layers ILD1 and ILD2 and a barrier pattern BM enclosing the conductive pattern CP. In various example embodiments, the conductive pattern CP may be formed of or include at least one of metallic materials (e.g., Ti, Mo, W, Cu, Al, Ta, Ru, Ir, and Co). As an example, the barrier pattern BM may be formed of or include at least one of metal nitride materials (e.g., nitride materials of Ti, Mo, W, Cu, Al, Ta, Ru, Ir, and Co). However, example embodiments are not limited thereto.

An ohmic pattern OM may be interposed between the active contact AC and the second pattern T2 of the source/drain pattern SD1 or SD2. Thus, contact resistance characteristics between the active contact AC and the second pattern T2 of the source/drain pattern SD1 or SD2 may be improved. In various example embodiments, the ohmic pattern OM may be formed of or include at least one of metal silicide materials (e.g., silicide materials of Ti, Mo, W, Cu, Al, Ta, Ru, Ir, and Co). However, example embodiments are not limited thereto.

Metal patterns MT may be provided in the third interlayer insulating layer ILD3. Vias VI may be interposed between the metal patterns MT and the active contacts AC. The metal patterns MT may be electrically connected to the active contacts AC through the vias VI. In various example embodiments, a gate contact GT may be connected to the gate electrode GE, and the metal pattern MT may be electrically connected to the gate contact GT through the via VI. In various example embodiments, although not illustrated in the drawings, a plurality of metal patterns MT and a plurality of vias VI may be alternately stacked to form a multi-layered structure. The metal patterns MT and the vias VI may be formed of or include at least one of metallic materials (e.g., Ti, Mo, W, Cu, Al, Ta, Ru, Ir, and Co). However, example embodiments are not limited thereto. In various example embodiments, the metal patterns MT in the third interlayer insulating layer ILD3 may be interconnection lines, which are used to deliver or apply a drain voltage.

The power delivery network layer PDN may be provided on the bottom surface of the substrate 105. The power delivery network layer PDN may include a plurality of lower interconnection lines (not shown), which are electrically connected to the source/drain patterns SD1 and SD2 through backside contacts BCS to be described below. In various example embodiments, the power delivery network layer PDN may include an interconnection network, which is used to apply a source voltage.

A backside contact BCS may be provided in the substrate 105. The backside contact BCS may penetrate the substrate 105 and may be interposed between the first pattern T1 of the source/drain pattern SD1 or SD2 and the power delivery network layer PDN. The backside contact BCS may electrically connect the first pattern T1 of the source/drain pattern SD1 or SD2 to the power delivery network layer PDN. That is, the backside contact BCS may be a backside active contact, which is formed through a backside surface of the substrate 105, unlike the active contact AC described above.

A top surface of the backside contact BCS may be located between top and bottom surfaces of the first semiconductor pattern SP1. A bottom surface of the backside contact BCS may be in contact with the lower interconnection line (not shown) of the power delivery network layer PDN. The top surface of the backside contact BCS may be in direct contact with the first pattern T1 of the source/drain pattern SD1 or SD2. In detail, the uppermost surface of the backside contact BCS may be in direct contact with the main layer MAL of the first pattern T1. The top surface of the backside contact BCS may be a curved surface that is convex toward the first pattern T1.

The backside contact BCS may include a backside conductive pattern BT and a backside barrier pattern BBM enclosing the backside conductive pattern BT. In various example embodiments, the backside conductive pattern BT may be formed of or include at least one of metallic materials (e.g., Ti, Mo, W, Cu, Al, Ta, Ru, Ir, and Co). However, example embodiments are not limited thereto. The backside barrier pattern BBM may be formed of or include at least one of metal nitride materials (e.g., nitrides of Ti, Mo, W, Cu, Al, Ta, Ru, Ir, and Co). However, example embodiments are not limited thereto.

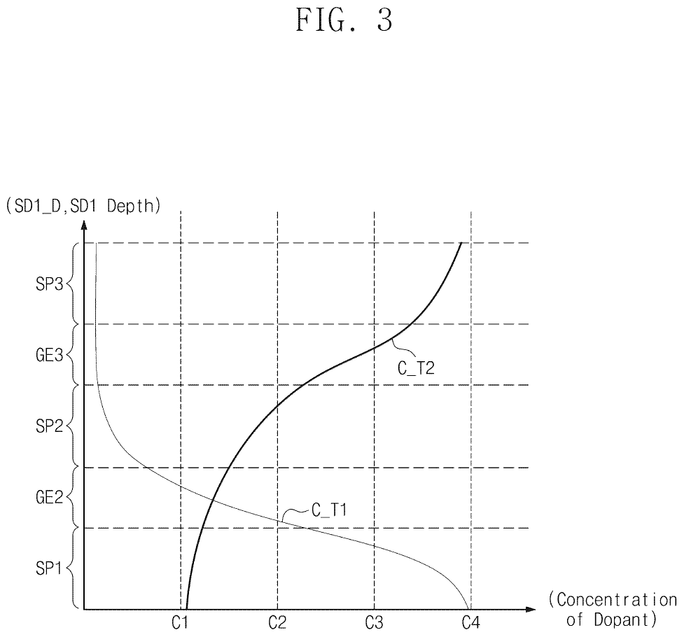

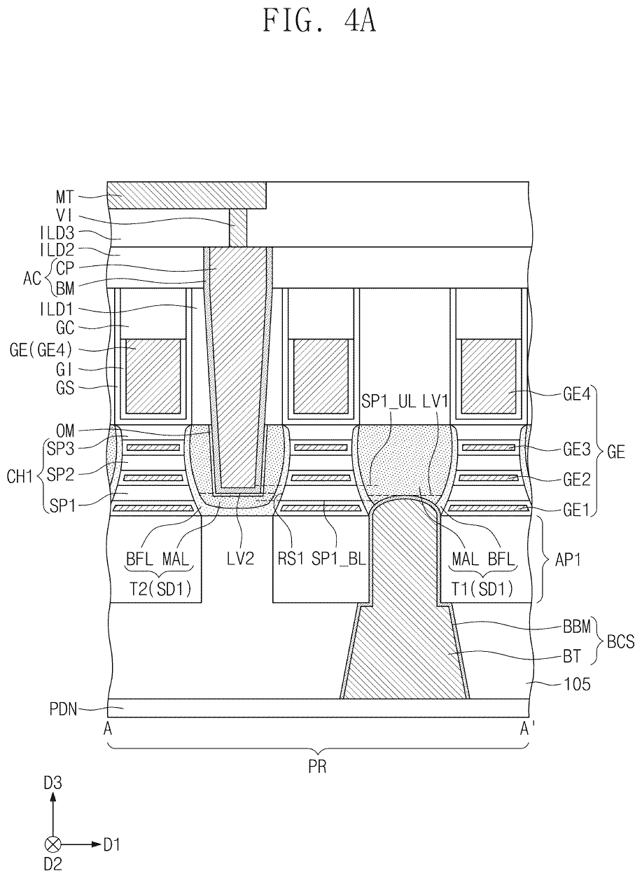

Referring to FIGS. 2A, 2B, and 3, the first source/drain pattern SD1 may contain p-type impurities (e.g., boron (B), gallium (Ga), or indium (In)), and the second source/drain pattern SD2 may contain n-type impurities (e.g., phosphorus (P), arsenic (As), or antimony (Sb)). However, example embodiments are not limited thereto.

The first pattern T1 of the source/drain pattern SD1 or SD2 may have a first doping concentration C_T1. The second pattern T2 of the source/drain pattern SD1 or SD2 may have a second doping concentration C_T2. The first and second doping concentrations C_T1 and C_T2 may be defined as doping concentrations of the impurities, which are contained in the source/drain patterns SD1 and SD2, respectively.

The first doping concentration C_T1 may gradually decrease in the third direction D3 perpendicular to the substrate 105, and the second doping concentration C_T2 may gradually increase in the third direction D3. As another example, the first doping concentration C_T1 may exponentially decrease in the third direction D3, and the second doping concentration C_T2 may exponentially increase in the third direction D3.

FIG. 3 show a change in each of the first and second doping concentrations C_T1 and C_T2 according to a depth SD1_D of the first source/drain pattern SD1. Here, the depth SD1_D of the first source/drain pattern SD1 may be a length of each of the first and second patterns T1 and T2 that corresponds to a vertical distance from a bottom surface of the first semiconductor pattern SP1 to a top surface of the third semiconductor pattern SP3. In other words, a region spanned by the depth SD1_D of the first source/drain pattern SD1 may include separate regions corresponding to the first to third semiconductor patterns SP1, SP2, and SP3 and the second and third inner electrodes GE2 and GE3, respectively.

The first pattern T1 may include a first region on a side surface of the first semiconductor pattern SP1, a second region on a side surface of the second semiconductor pattern SP2, and a third region on a side surface of the third semiconductor pattern SP3. The second pattern T2 may include a fourth region on an opposite side surface of the first semiconductor pattern SP1, a fifth region on an opposite side surface of the second semiconductor pattern SP2, and a sixth region on an opposite side surface of the third semiconductor pattern SP3. The first and fourth regions may be regions corresponding to a height SP1_H of the first semiconductor pattern SP1. The second and fifth regions may be regions corresponding to a height of the second semiconductor pattern SP2. The third and sixth regions may be regions corresponding to a height of the third semiconductor pattern SP3.

The first doping concentration C_T1 in the first region may range from a second concentration C2 to a fourth concentration C4. The first doping concentration C_T1 in the second and third regions may range from 0 to a first concentration C1. The first doping concentration C_T1 may be higher in the first region than in each of the second and third regions.

The second doping concentration C_T2 in the fourth region may range from the first concentration C1 to the second concentration C2. The second doping concentration C_T2 in the fifth region may range from the first concentration C1 to a third concentration C3. The second doping concentration C_T2 in in the sixth region may range from the third concentration C3 to the fourth concentration C4. The second doping concentration C_T2 may be higher in the sixth region than in each of the fourth and fifth regions. The second doping concentration C_T2 may be higher in the fifth region than in the fourth region.

In various example embodiments, the first concentration C1 may be 1.0×10¹⁸ atom/cm³, and the second concentration C2 may be 1.0×10¹⁹ atom/cm³. The third concentration C3 may be 1.0×10²⁰ atom/cm³, and the fourth concentration C4 may be 5.0×10²² atom/cm³.

The first doping concentration C_T1 in the first region of the first pattern T1 may be higher than the second doping concentration C_T2 in the fourth region of the second pattern T2. This is because, before a step of forming the backside contact BCS in a subsequent fabricating process, an ion implantation process is performed through the backside surface of the substrate 105. That is, since the ion implantation process is performed on the backside surface of the substrate, not the frontside surface, by adjusting the dose and energy conditions for the ion implantation process, it may be possible to selectively activate a desired one of the semiconductor patterns of the channel pattern CH1 or CH2. In various example embodiments, the first semiconductor pattern SP1 of the channel pattern CH1 or CH2 may be selectively activated.

For example, by adjusting the doping concentration C_T1 or CT_2 of each of the first and second patterns T1 and T2, at least one of the first to third semiconductor patterns SP1, SP2, and SP3 may be selected as an electrical path for conduction of charge carriers. For example, only the first semiconductor pattern SP1 may be selected as the electrical path for conduction of charge carriers.

The second doping concentration C_T2 in the fourth region of the second pattern T2 may be a concentration of impurities contained in a lower portion of the second pattern T2. In detail, an ion implantation process may be performed to inject ions or impurities into an upper portion of the second pattern T2 through the frontside of the substrate 105, and in this case, during a subsequent annealing process, the injected ions or impurities may be diffused into the lower portion of the second pattern T2. The second doping concentration C_T2 in the fourth region may be determined by a concentration of the ions or impurities, which are diffused from the upper portion of the second pattern T2, and thus, the second doping concentration C_T2 may be lower in the fourth region than in the fifth and sixth regions.

The first doping concentration C_T1 in the first region of the first pattern T1 may be a concentration of impurities contained in a lower portion of the first pattern T1. In detail, an ion implantation process may be directly performed to inject ions or impurities into the lower portion of the first pattern T1 through the backside surface of the substrate 105, and in this case, the injected ions or impurities may be diffused into an upper portion of the first pattern T1. In other words, since the ion implantation process is performed on the lower portion of the first pattern T1 under targeted conditions of dose and energy, the first doping concentration C_T1 in the first region may be higher than those in the second and third regions. In this case, since the first doping concentration C_T1 has a relatively high value in the first region, by forming the backside contact BCS to an appropriate depth, it may be possible to reduce or prevent the source/drain pattern from being damaged by stress applied thereto. Thus, the reliability characteristics of the semiconductor device may be improved.

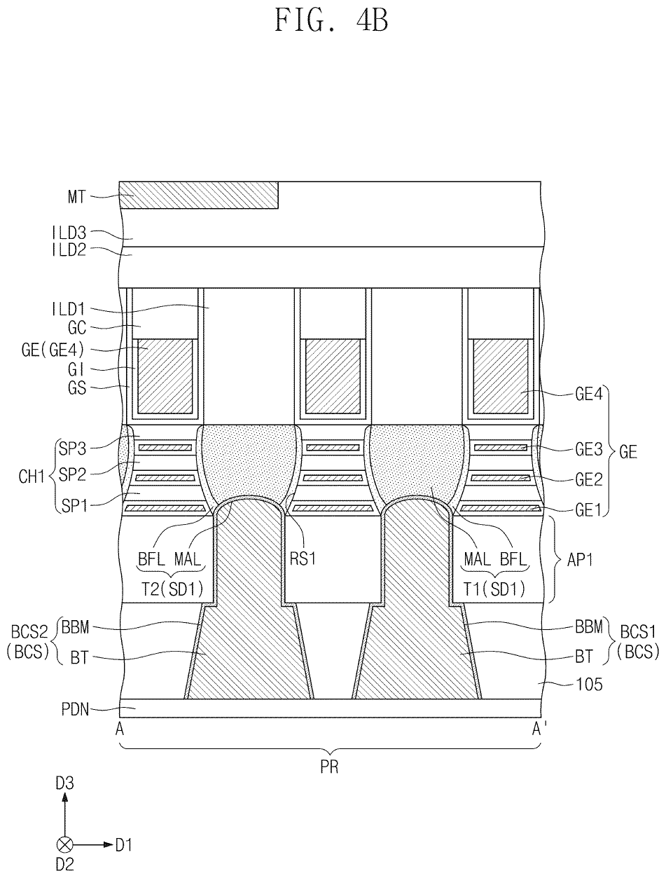

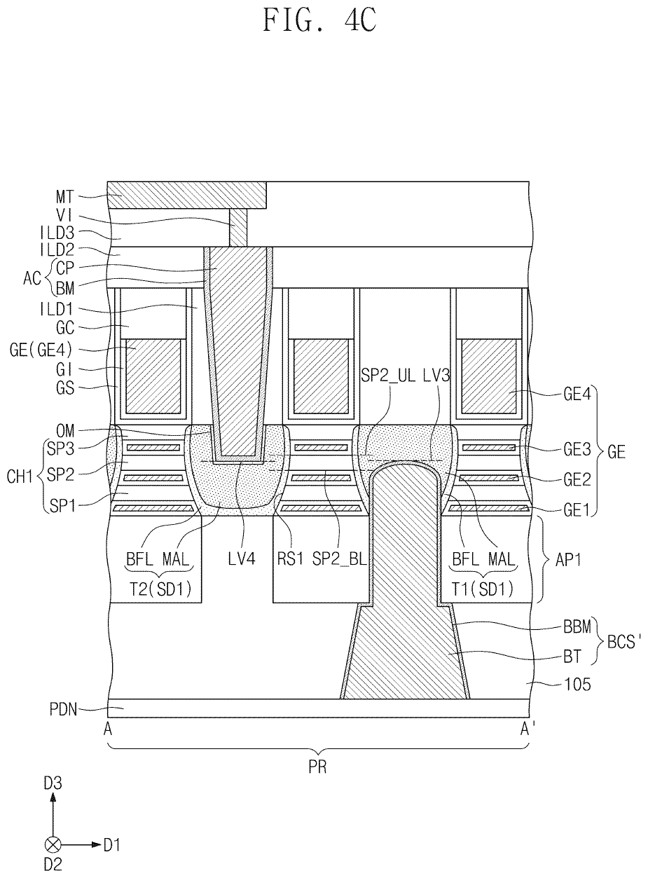

Hereinafter, a semiconductor device according to various example embodiments of the inventive concepts will be described in more detail with reference to FIGS. 4A to 4C. In the following description, a previously-described element may be identified by the same reference number without repeating an overlapping description thereof, for concise description.

Referring to FIG. 4A, the uppermost surface of the backside contact BCS may be located at a first level LV1 in the third direction D3. The bottom surface of the active contact AC may be located at a second level LV2 in the third direction D3. The first and second levels LV1 and LV2 may be located between a top surface level SP1_UL of the first semiconductor pattern SP1 and a bottom surface level SP1_BL of the first semiconductor pattern SP1. That is, the first and second levels LV1 and LV2 may be higher than the bottom surface of the first semiconductor pattern SP1 and may be lower than the top surface of the first semiconductor pattern SP1. The second level LV2 may be higher than or equal to the first level LV1.

The active contact AC may be extended to be buried in a lower portion of the second pattern T2. For example, the active contact AC may be formed from the frontside of the substrate 105 to be buried in upper and lower portions of the second pattern T2. The active contact AC may be buried in the main layer MAL of the second pattern T2 and may not be in direct contact with the buffer layer BFL of the second pattern T2. The uppermost surface of the backside contact BCS may be in direct contact with the main layer MAL of the first pattern T1.

Referring to FIG. 4B, the backside contacts BCS may be provided to be in direct contact with the first and second patterns T1 and T2 of the source/drain pattern SD1. The backside contacts BCS may include a first backside contact BCS1, which is electrically connected to the first pattern T1 and a second backside contact BCS2, which is electrically connected to the second pattern T2. In other words, the active contact of FIG. 2A, which is formed from the frontside of the substrate 105 to be buried in the upper portion of the second pattern T2, may not be formed.

The power delivery network layer PDN may be provided on the bottom surface of the substrate 105. In detail, the lower interconnection lines (not shown) in the power delivery network layer PDN may be provided below each of the first and second backside contacts BCS1 and BCS2 and may be electrically connected to the source/drain pattern SD1. In this case, the lower interconnection line, which is provided below the first backside contact BCS1, may be used to deliver or apply a drain voltage, and the lower interconnection line, which is provided below the second backside contact BCS2, may be used to deliver or apply a source voltage. The lower interconnection lines may be patterns that are provided in the power delivery network layer PDN and are horizontally separated from each other.

Each of the first and second backside contacts BCS1 and BCS2 may include a first portion, which is provided in the substrate 105, and a second portion, which is provided on the first portion. The second portion may be provided in the first active pattern AP1. A width of the first portion in the first direction D1 may decrease as a height in the third direction D3 increases. A width of the second portion in the first direction D1 may be maintained at a constant value and then decreased, as a height in the third direction D3 increases. In detail, the width of the second portion may be constant between the first active pattern AP1 and may decrease as it approaches the source/drain pattern SD1.

The uppermost surface of the first backside contact BCS1 may be in direct contact with the main layer MAL of the first pattern T1, and the uppermost surface of the second backside contact BCS2 may be in direct contact with the main layer MAL of the second pattern T2. The uppermost surfaces of the first and second backside contacts BCS1 and BCS2 may be located at the same level or at different levels in the third direction D3. As an example, the uppermost surface of the first backside contact BCS1 may be higher than the uppermost surface of the second backside contact BCS2, and as another example, the uppermost surface of the first backside contact BCS1 may be lower than the uppermost surface of the second backside contact BCS2.

In various example embodiments, since the ion implantation process is performed on the backside surface of the substrate, not the frontside, before the forming of the backside contacts BCS, by adjusting the dose and energy conditions for the ion implantation process, it may be possible to selectively activate a desired one of the semiconductor patterns of the channel pattern CH1.

Referring to FIG. 4C, the uppermost surface of a backside contact BCS′ may be located at a third level LV3 in the third direction D3. The bottom surface of the active contact AC may be located at a fourth level LV4 in the third direction D3. The third and fourth levels LV3 and LV4 may be located between a top surface level SP2_UL of the second semiconductor pattern SP2 and a bottom surface level SP2_BL of the second semiconductor pattern SP2. In other words, the third and fourth levels LV3 and LV4 may be higher than a bottom surface of the second semiconductor pattern SP2 and may be lower than a top surface of the second semiconductor pattern SP2. The fourth level LV4 may be higher than or equal to the third level LV3.

The active contact AC may be extended to be buried in an intermediate portion of the second pattern T2. In other words, the active contact AC may be formed from the frontside of the substrate 105 to be buried in the upper and intermediate portions of the second pattern T2. The active contact AC may be buried in the main layer MAL of the second pattern T2 and may not be in direct contact with the buffer layer BFL of the second pattern T2. The uppermost surface of the backside contact BCS′ may be in direct contact with the main layer MAL of the first pattern T1.

In this case, the second semiconductor pattern SP2 of the channel pattern CH1 may be selectively activated. As another example, the first and second semiconductor patterns SP1 and SP2 may be selectively activated.

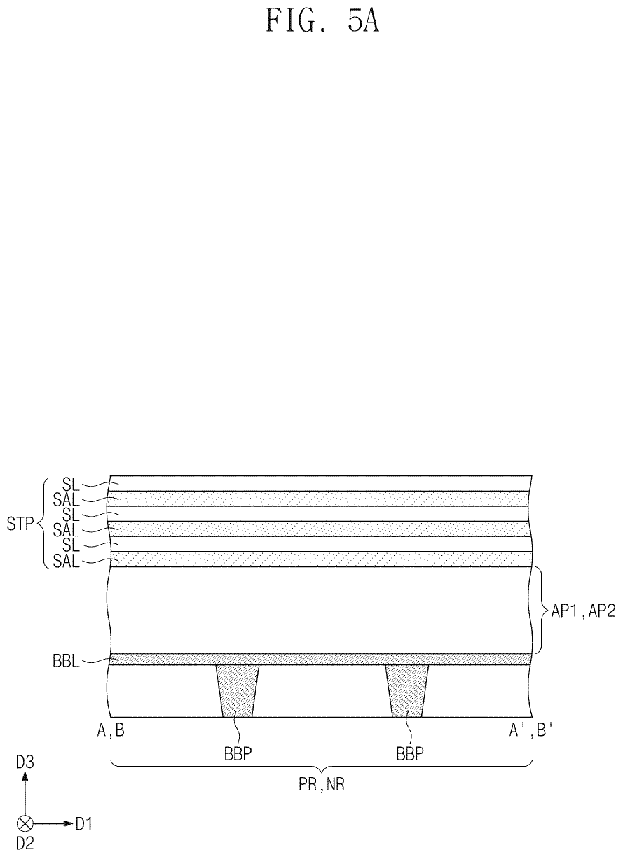

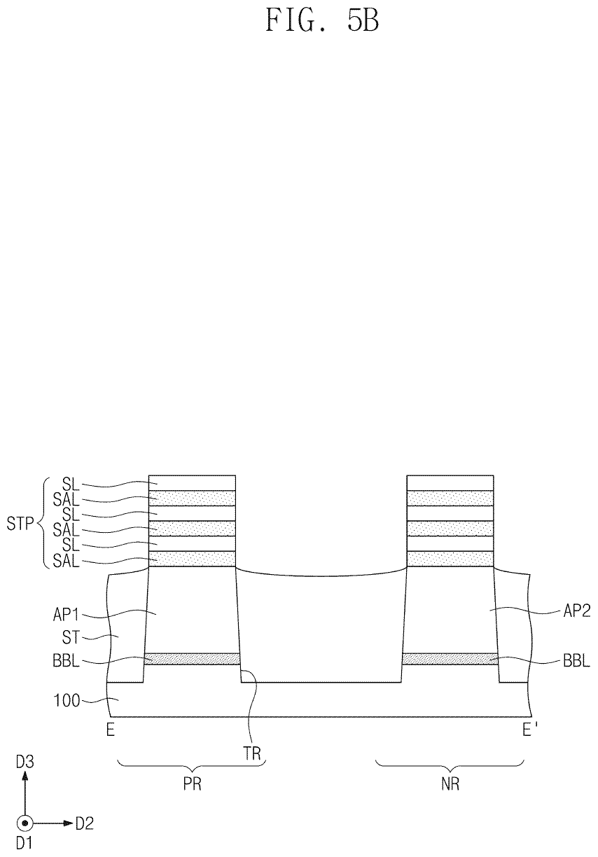

FIGS. 5A to 13C are diagrams illustrating a method of fabricating a semiconductor device according to various example embodiments of the inventive concepts.

Referring to FIGS. 1, 5A, and 5B, a semiconductor substrate 100 including PMOSFET and NMOSFET regions PR and NR may be provided. In various example embodiments, the semiconductor substrate 100 may be a single-crystalline silicon wafer, a silicon-germanium wafer, or a semiconductor substrate (e.g., a silicon-on-insulator (SOI) substrate) including a semiconductor material. However, example embodiments are not limited thereto.

Trenches may be formed in the semiconductor substrate 100, and lower supporting patterns BBP may be formed to fill the trenches. The lower supporting patterns BBP may be formed through a SEG process, in which the semiconductor substrate 100 is used as a seed layer, to fill the trenches. An intermediate layer BBL may be formed to cover the semiconductor substrate 100 and the lower supporting patterns BBP. The intermediate layer BBL may be formed through a SEG process using the semiconductor substrate 100 and the lower supporting patterns BBP as a seed layer. In various example embodiments, the lower supporting patterns BBP and the intermediate layer BBL may be formed of or include silicon-germanium (SiGe). A silicon single crystalline layer may be additionally formed on the intermediate layer BBL. The semiconductor substrate 100 may refer to a structure including the silicon single crystalline layer.

Stacking patterns STP may be formed on the PMOSFET and NMOSFET regions PR and NR. In various example embodiments, the formation of the stacking patterns STP may include alternately stacking semiconductor layers SL and sacrificial layers SAL on the semiconductor substrate 100, forming mask patterns (not shown) to extend in the first direction D1, and performing a patterning process using the mask patterns as an etch mask. During the patterning process, portions of the semiconductor substrate 100 may be removed to form the trenches TR defining the first and second active patterns AP1 and AP2.

The first active pattern AP1 may be formed on the PMOSFET region PR, and the second active pattern AP2 may be formed on the NMOSFET region NR. The first and second active patterns AP1 and AP2 may be extended in the first direction D1. The device isolation patterns ST may be formed to fill the trenches TR.

The sacrificial layers SAL may include a material having an etch selectivity with respect to the semiconductor layers SL. Thus, the semiconductor layers SL may not be substantially removed or may be less removed in a subsequent process of removing the sacrificial layers SAL. The semiconductor and sacrificial layers SL and SAL may be formed of or include at least one of silicon (Si), germanium (Ge), or silicon germanium (SiGe), but the material of the sacrificial layers SAL may be different from that of the semiconductor layers SL.

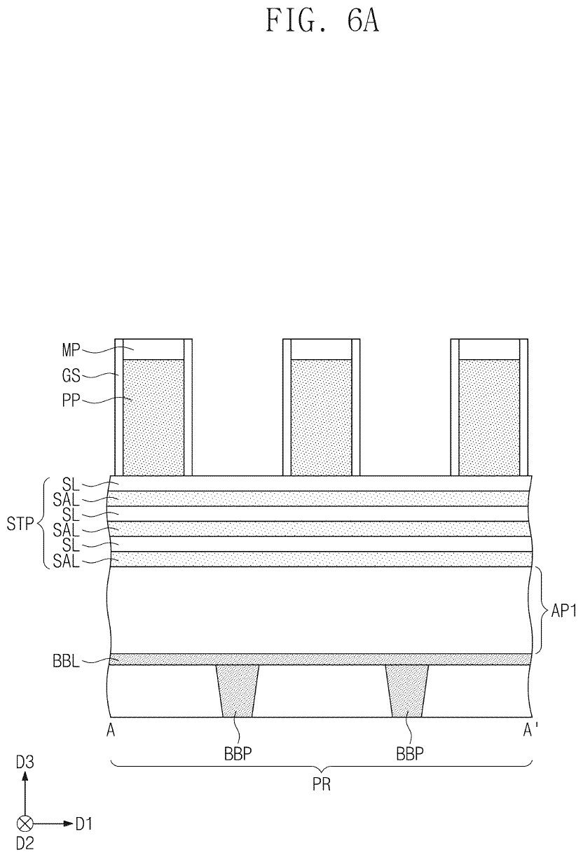

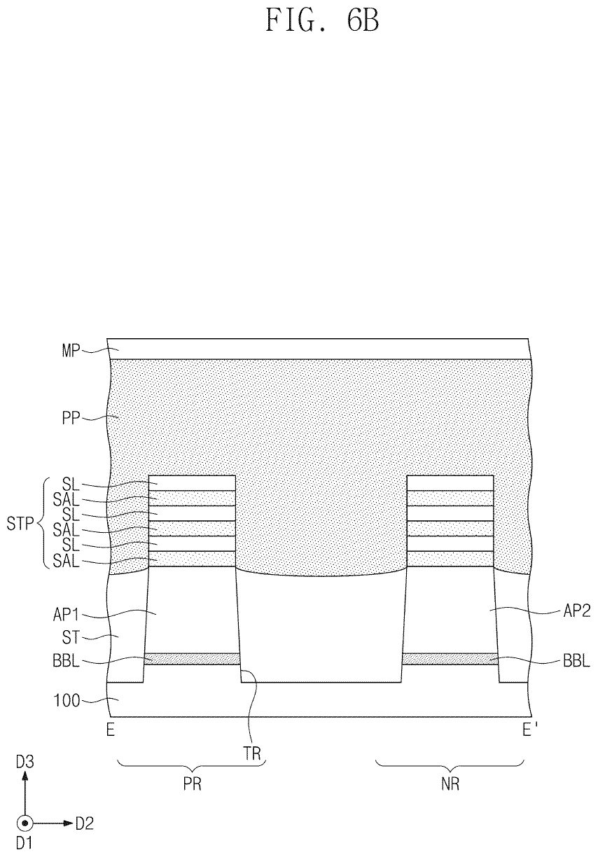

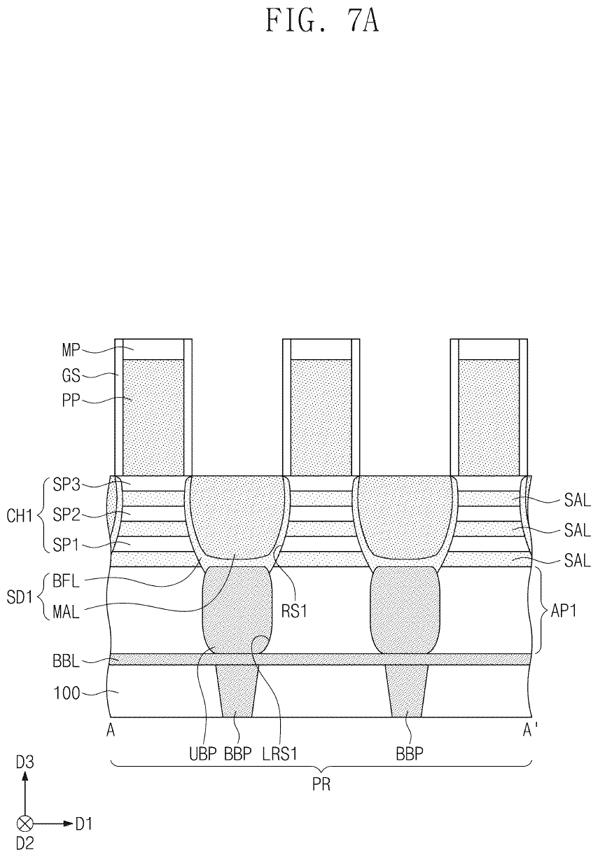

Referring to FIGS. 1, 6A, and 6B, sacrificial patterns PP may be formed on the semiconductor substrate 100 to extend in the second direction D2. The sacrificial patterns PP may be formed to cover the top surfaces of the device isolation patterns ST and the side and top surfaces of the stacking patterns STP. In various example embodiments, the formation of the sacrificial patterns PP may include forming a sacrificial layer (not shown) on the semiconductor substrate 100, forming hard mask patterns MP on the sacrificial layer, and removing a portion of the sacrificial layer using the hard mask patterns MP as an etch mask to form the sacrificial patterns PP. In various example embodiments, the sacrificial pattern PP may be formed of or include polysilicon. Next, the gate spacers GS may be formed on side surfaces of the sacrificial patterns PP.

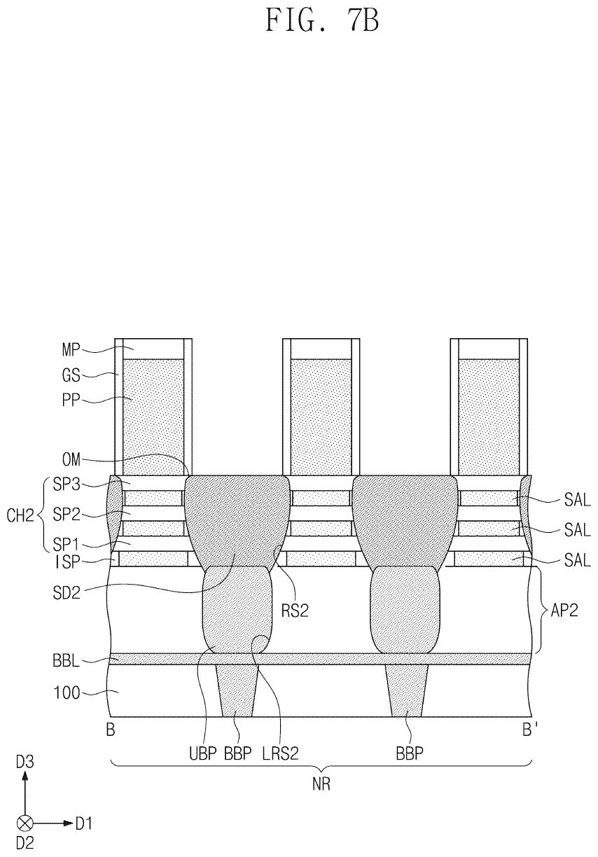

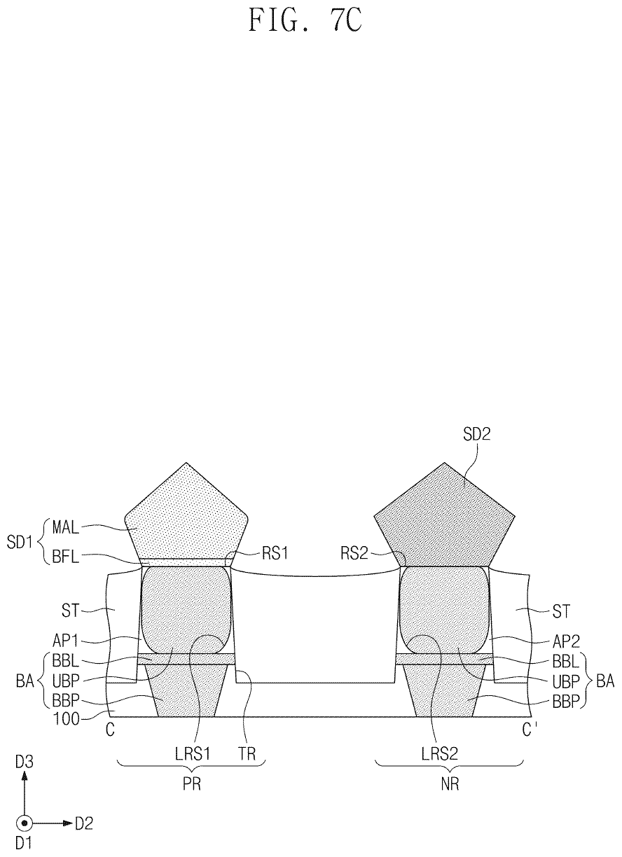

Referring to FIGS. 1 and 7A to 7C, the first recesses RS1 may be formed in the stacking pattern STP on the first active pattern AP1. The second recesses RS2 may be formed in the stacking pattern STP on the second active pattern AP2. In various example embodiments, the first and second recesses RS1 and RS2 may be formed by removing portions of the stacking pattern STP using the hard mask patterns MP as an etch mask.

The semiconductor layers SL on the first active pattern AP1 may be divided into the first channel patterns CH1, which are spaced apart from each other in the first direction D1, by the first recesses RS1. The semiconductor layers SL on the second active pattern AP2 may be divided into the second channel patterns CH2, which are spaced apart from each other in the first direction D1, by the second recesses RS2. Each of the first and second channel patterns CH1 and CH2 may include the first to third semiconductor patterns SP1, SP2, and SP3.

A portion of the sacrificial layer SAL, which is exposed by the second recess RS2, may be replaced with an insulating material, and thus, the inner spacers ISP may be formed on opposite side surfaces of the sacrificial layer SAL (e.g., see FIG. 7B).

A first lower recess LRS1 may be formed below the first recess RS1. A second lower recess LRS2 may be formed below the second recess RS2. Upper supporting patterns UBP may be formed by a SEG process, in which the semiconductor substrate 100 is used as a seed layer, to fill the first and second lower recesses LRS1 and LRS2. In various example embodiments, the upper supporting patterns UBP may be formed of or include silicon-germanium (SiGe).

Referring to FIG. 7C, the lower supporting pattern BBP, the intermediate layer BBL, and the upper supporting pattern UBP may constitute a backside alignment pattern BA. The backside alignment pattern BA may be provided below each of the first and second source/drain patterns SD1 and SD2 to be described below. Since the lower supporting pattern BBP, the intermediate layer BBL, and the upper supporting pattern UBP include the same material (e.g., silicon-germanium), there may be no distinct boundary between the lower supporting pattern BBP, the intermediate layer BBL, and the upper supporting pattern UBP of the backside alignment pattern BA, unlike the illustrated example.

The first source/drain patterns SD1 may be formed in the first recesses RS1. The first source/drain patterns SD1 may be formed by a SEG process, in which the first to third semiconductor patterns SP1, SP2, and SP3 and the backside alignment patterns BA on the PMOSFET region PR are used as a seed layer. In detail, the first source/drain patterns SD1 may be formed by performing a SEG process using the first to third semiconductor patterns SP1, SP2, and SP3 and the upper supporting pattern UBP as a seed layer.

As an example, when the first source/drain pattern SD1 is formed, the first source/drain pattern SD1 may be an impurity-free or undoped pattern. For example, after the formation of the first source/drain pattern SD1, p-type impurities may be injected into the first source/drain pattern SD1. As another example, during the process of forming the first source/drain pattern SD1, p-type impurities (e.g., boron, gallium, or indium, however, example embodiments are not limited thereto) may be injected into the first source/drain pattern SD1 in an in-situ manner.

The second source/drain patterns SD2 may be formed in the second recesses RS2. The second source/drain patterns SD2 may be formed through a SEG process, in which the first to third semiconductor patterns SP1, SP2, and SP3 and the backside alignment patterns BA on the NMOSFET region NR are used as a seed layer. In detail, the second source/drain patterns SD2 may be formed by performing a SEG process using the first to third semiconductor patterns SP1, SP2, and SP3 and the upper supporting pattern UBP as a seed layer.

As an example, when the second source/drain pattern SD2 is formed, the second source/drain pattern SD2 may be an impurity-free or undoped pattern. For example, after the formation of the second source/drain pattern SD2, n-type impurities may be injected into the second source/drain pattern SD2. As another example, during the process of forming the second source/drain pattern SD2, n-type impurities (e.g., phosphorus, arsenic, or antimony, however, example embodiments are not limited thereto) may be injected into the second source/drain pattern SD2 in an in-situ manner.

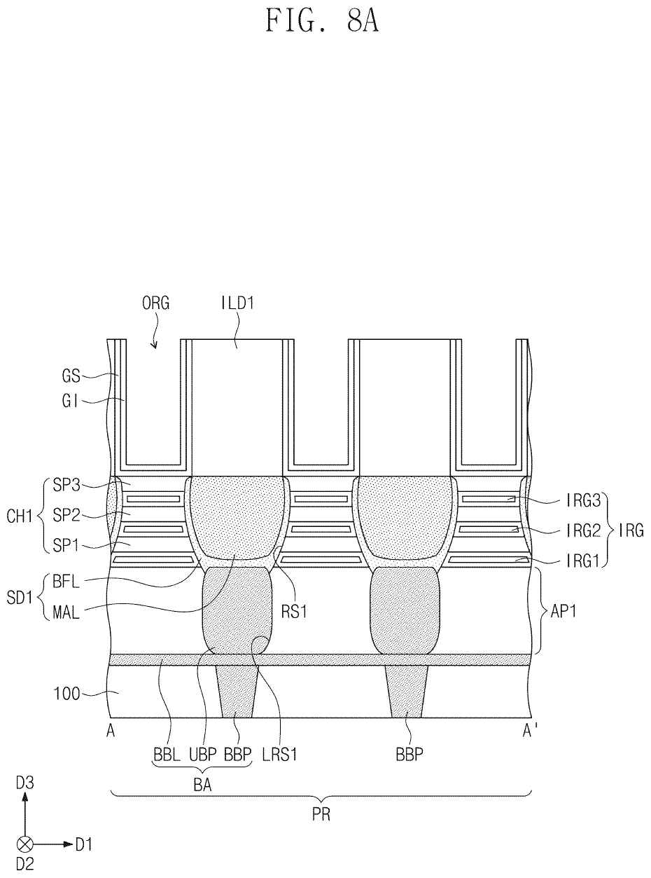

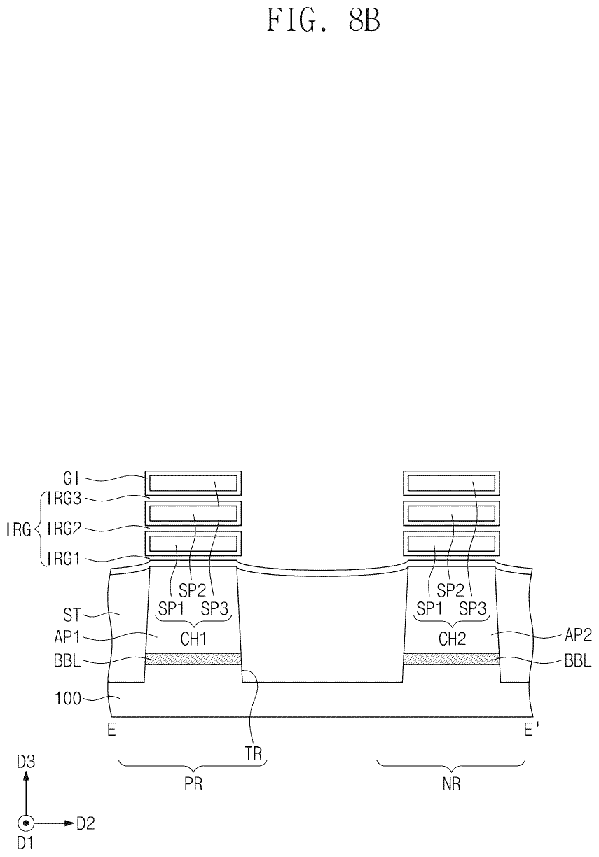

Referring to FIGS. 1, 8A, and 8B, the first interlayer insulating layer ILD1 may be formed to cover the first and second source/drain patterns SD1 and SD2, the hard mask patterns MP, and the gate spacers GS. Next, the first interlayer insulating layer ILD1 may be removed from top surfaces of the sacrificial patterns PP. In various example embodiments, the removal process may also be performed to remove the hard mask patterns MP and consequently to expose the sacrificial patterns PP.

Thereafter, the exposed sacrificial patterns PP may be removed to form empty spaces, which will be referred to as outer regions ORG. The first and second channel patterns CH1 and CH2 and the sacrificial layers SAL may be exposed to the outside through the outer region ORG.

Next, the exposed sacrificial layers SAL may be selectively removed. Here, due to the high etch selectivity between the sacrificial layers SAL and the first to third semiconductor patterns SP1, SP2, and SP3, it may be possible to limit, prevent, or suppress the first to third semiconductor patterns SP1, SP2, and SP3 from being removed during the process of removing the sacrificial layers SAL.

Inner regions IRG may be empty spaces, which are formed by removing the sacrificial layers SAL. In detail, the inner regions IRG may be formed between the first to third semiconductor patterns SP1, SP2, and SP3. The inner regions IRG may include first to third inner regions IRG1, IRG2, and IRG3, which are spaced apart from each other in the third direction D3.

The gate insulating pattern GI may be formed in each of the inner regions IRG and the outer region ORG. The gate insulating pattern GI may be formed to enclose each of the first to third semiconductor patterns SP1, SP2, and SP3. The gate insulating pattern GI may be formed to have a constant thickness.

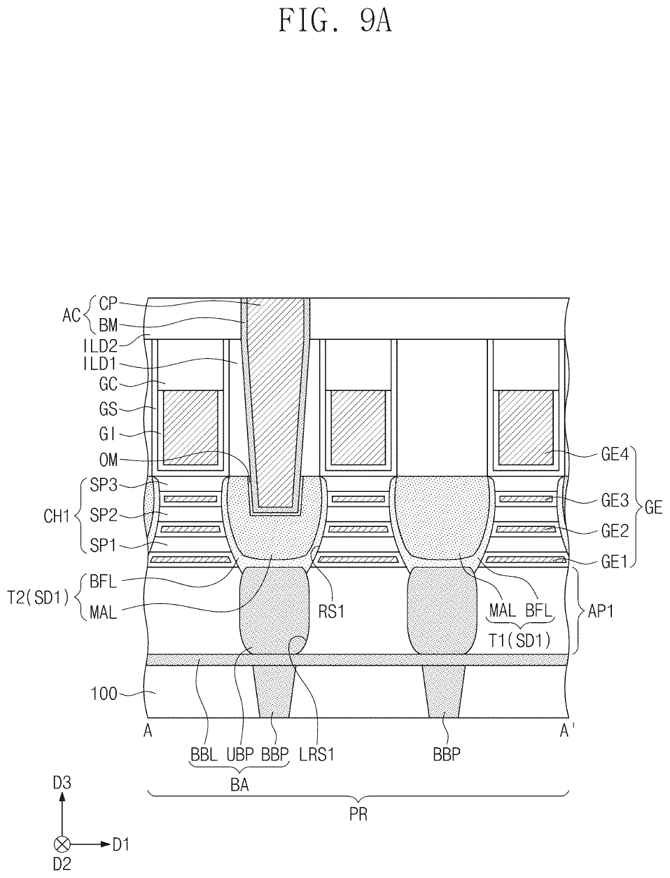

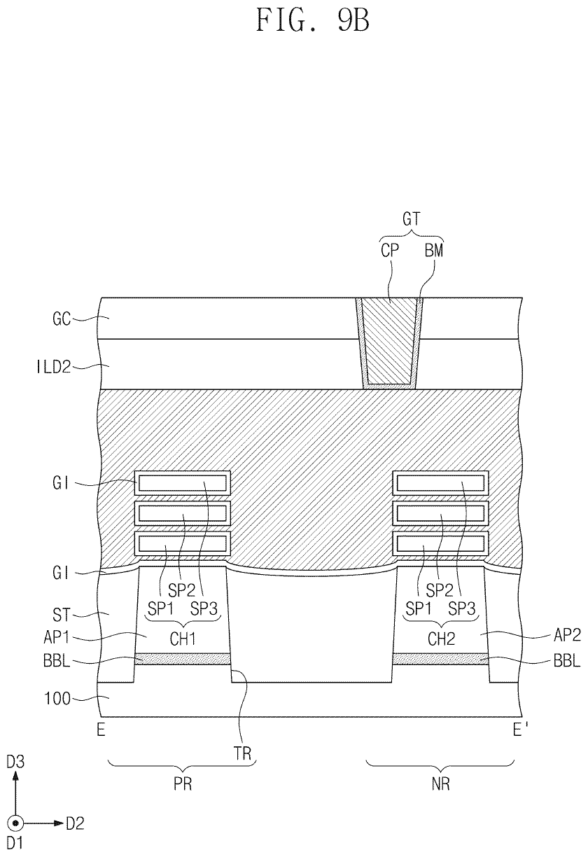

Referring to FIGS. 1, 9A, and 9B, the gate electrode GE may be formed on the gate insulating pattern GI. The gate electrode GE may include the inner electrodes (e.g., the first to third inner electrodes GE1, GE2, and GE3), which are formed in the first to third inner regions IRG1, IRG2, and IRG3, respectively, and the outer electrode GE4, which is formed in the outer region ORG. Next, the gate capping pattern GC may be formed on the outer electrode GE4.

The second interlayer insulating layer ILD2 may be formed on the first interlayer insulating layer ILD1 and the gate capping pattern GC. Mask patterns (not shown) may be formed on the second interlayer insulating layer ILD2. A recessing process may be performed on the first and second interlayer insulating layers ILD1 and ILD2, using the mask patterns, until upper portions of the source/drain patterns SD1 and SD2 are recessed. The recessing process may include a dry etching process that is performed on the first and second interlayer insulating layers ILD1 and ILD2 and the source/drain patterns SD1 and SD2.

An ion implantation process may be performed on the frontside of the substrate 105 to inject impurities into the recessed regions. For example, the ion implantation process may be performed to inject impurities into the first source/drain pattern SD1. For example, p-type impurities may be injected into the undoped first source/drain pattern SD1. The ion implantation process may be performed to inject impurities into the second source/drain pattern SD2. For example, n-type impurities may be injected into the undoped second source/drain pattern SD2.

The active contacts AC may be formed to penetrate the first and second interlayer insulating layers ILD1 and ILD2 and may be connected to the first and second source/drain patterns SD1 and SD2, respectively. Each of the first and second source/drain patterns SD1 and SD2 may include the first pattern T1, which is not connected to the active contact AC, and the second pattern T2, which is electrically connected to the active contact AC.

The gate contacts GT may be formed to penetrate the second interlayer insulating layer ILD2 and the gate capping pattern GC and may be connected to the gate electrodes GE.

The formation of the active and gate contacts AC and GT may include forming the barrier pattern BM and forming the conductive pattern CP on the barrier pattern BM. The ohmic pattern OM may be further formed between the active contact AC and the second pattern T2 of each of the first and second source/drain patterns SD1 and SD2.

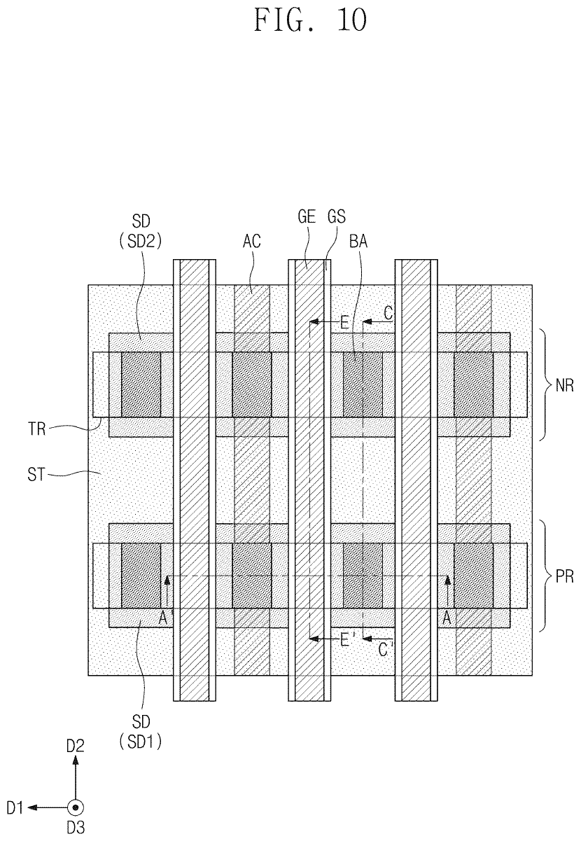

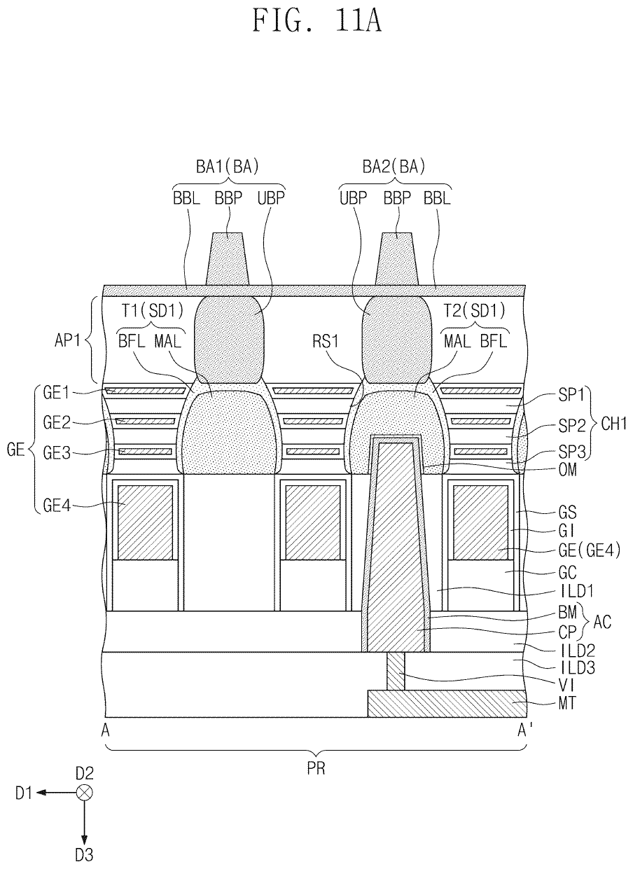

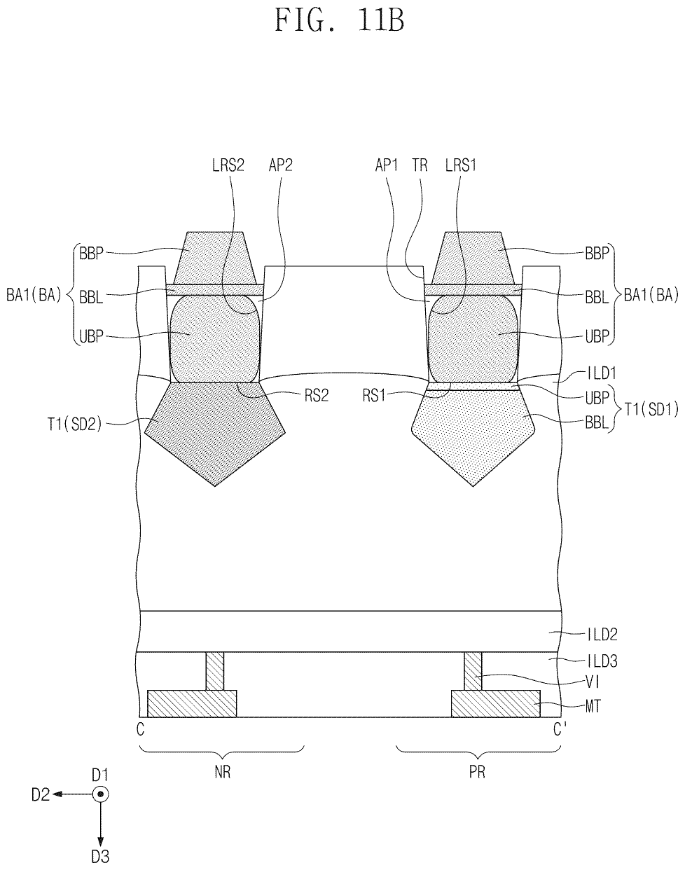

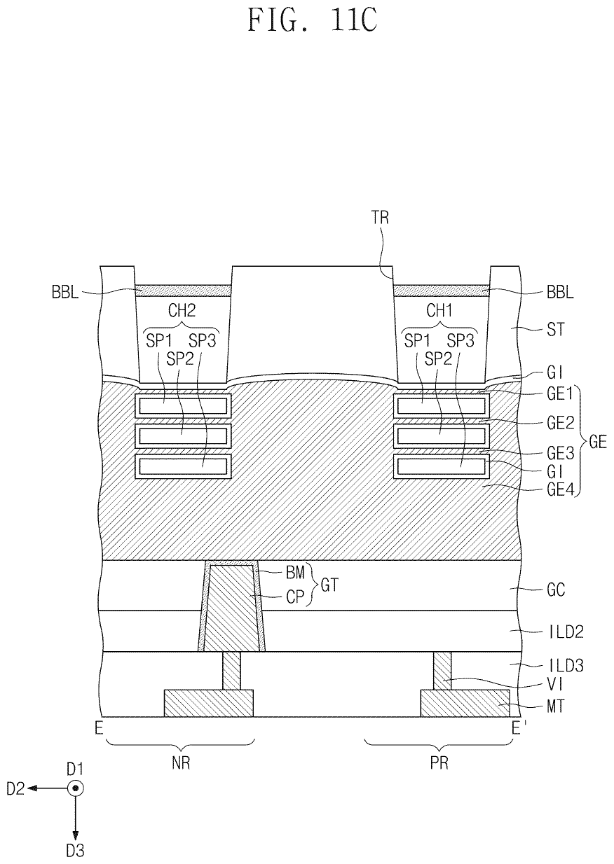

Referring to FIGS. 10 and 11A to 11C, the third interlayer insulating layer ILD3 may be formed on the second interlayer insulating layer ILD2 and the active contacts AC. The metal patterns MT and the vias VI may be formed in the third interlayer insulating layer ILD3.

The semiconductor substrate 100 of FIGS. 4A and 4B may be inverted after a back-end-of-line (BEOL) process. Since the semiconductor substrate 100 of FIG. 4A is inverted, the terms ‘top surface’ and ‘upper portion’ in the following description of FIGS. 10 to 11C may mean the ‘bottom surface’ and ‘lower portion’, respectively, in the final structure of the semiconductor device described with reference to FIGS. 2A to 2E, and the terms ‘bottom surface’ and ‘lower portion’ may mean the ‘top surface’ and ‘upper portion’, respectively, in the final structure of the semiconductor device described with reference to FIGS. 2A to 2E.

Referring back to FIGS. 11A to 11C, after the BEOL process is finished, the semiconductor substrate 100 may be inverted such that a bottom surface of the semiconductor substrate 100 is exposed. The exposed portion of the semiconductor substrate 100 may be removed.

In various example embodiments, the removal of the portion of the semiconductor substrate 100 may include performing a planarization process on the bottom surface of the semiconductor substrate 100 to reduce a thickness of the semiconductor substrate 100 and performing a cleaning process on the semiconductor substrate 100 to selectively remove silicon (Si). The cleaning process may be performed to expose the intermediate layer BBL and the lower supporting pattern BBP of the backside alignment pattern BA. The backside alignment patterns BA may include a first backside alignment pattern BA1, which is provided below the first pattern T1, and a second backside alignment pattern BA2, which is provided below the second pattern T2. That is, after the partial removal of the semiconductor substrate 100, the intermediate layer BBL, the lower supporting pattern BBP, and the device isolation pattern ST may be exposed.

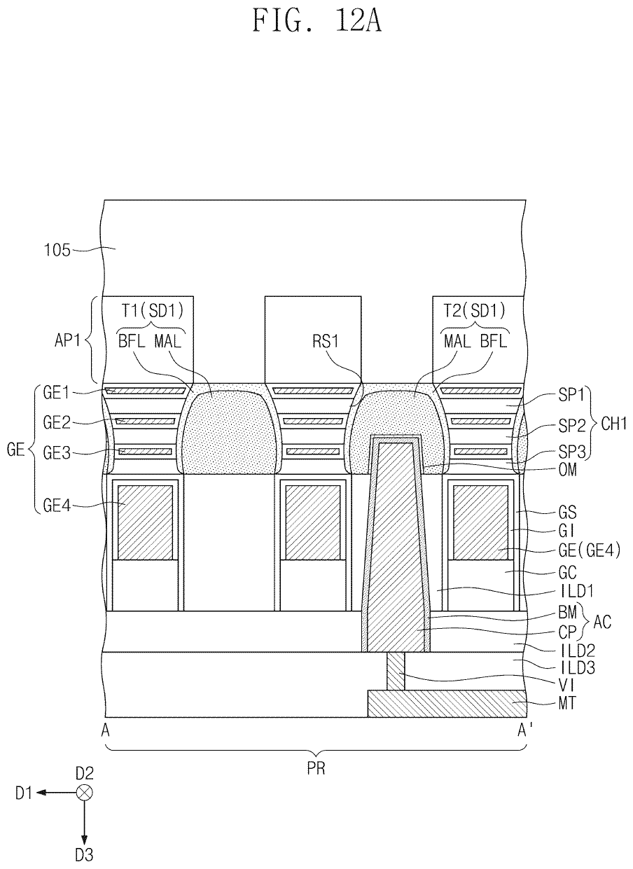

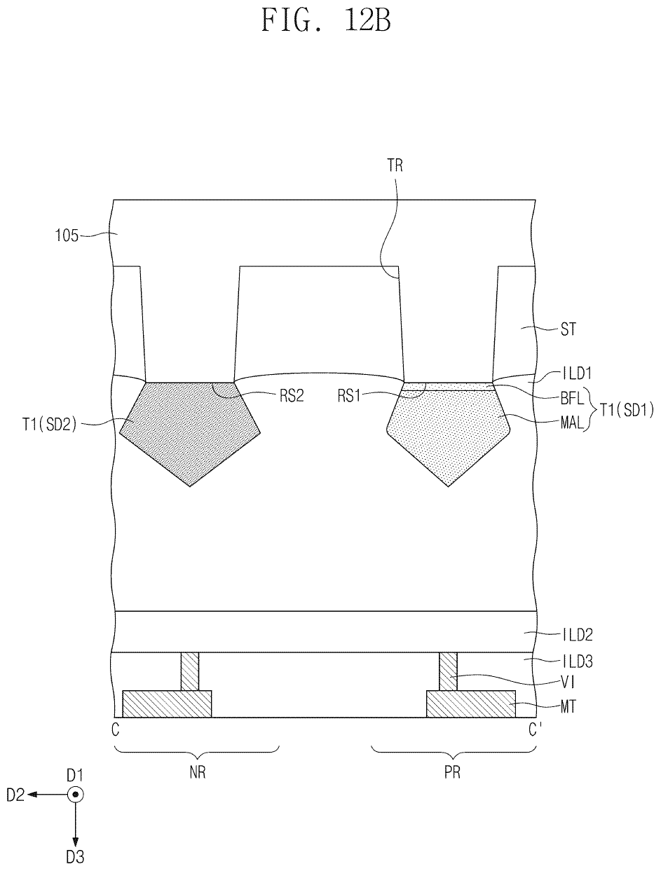

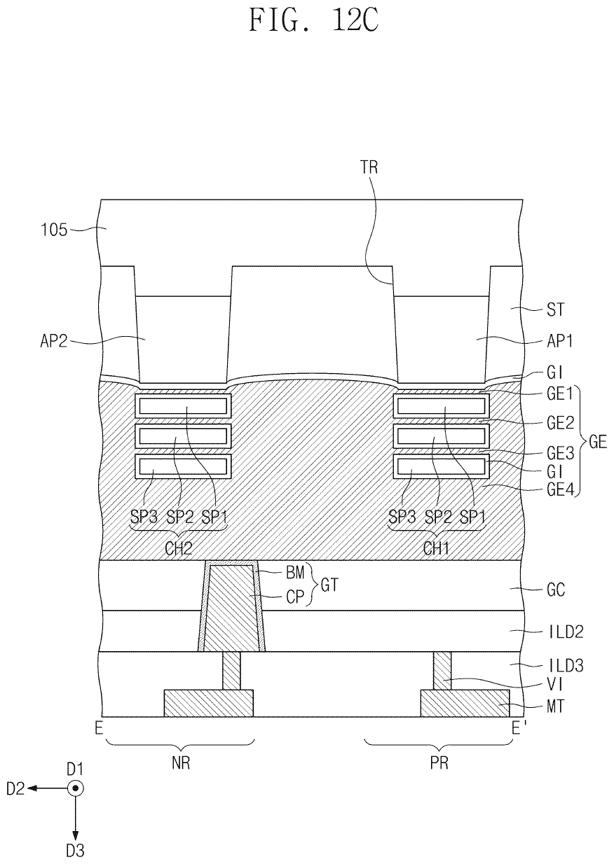

Referring to FIGS. 1 and 12A to 12C, an etching process may be performed to selectively remove the backside alignment patterns BA exposed. The etching process may be a dry etching process or a wet etching process. The device isolation pattern ST and the first and second active patterns AP1 and AP2 may be exposed, after the etching process.

The substrate 105 may be formed to fill a region which is formed as a result of removal of the semiconductor substrate 100 of FIG. 4A and the backside alignment patterns BA. In detail, the substrate 105 may be formed to fill back-side trenches, which are formed after the removal of the backside alignment patterns BA. In various example embodiments, the substrate 105 may be formed by filling an insulating material to a level that is higher than the empty region formed by removing the semiconductor substrate 100 of FIG. 4A. Next, a chemical mechanical polishing (CMP) process may be performed using a structure around the substrate 105 as a stop layer.

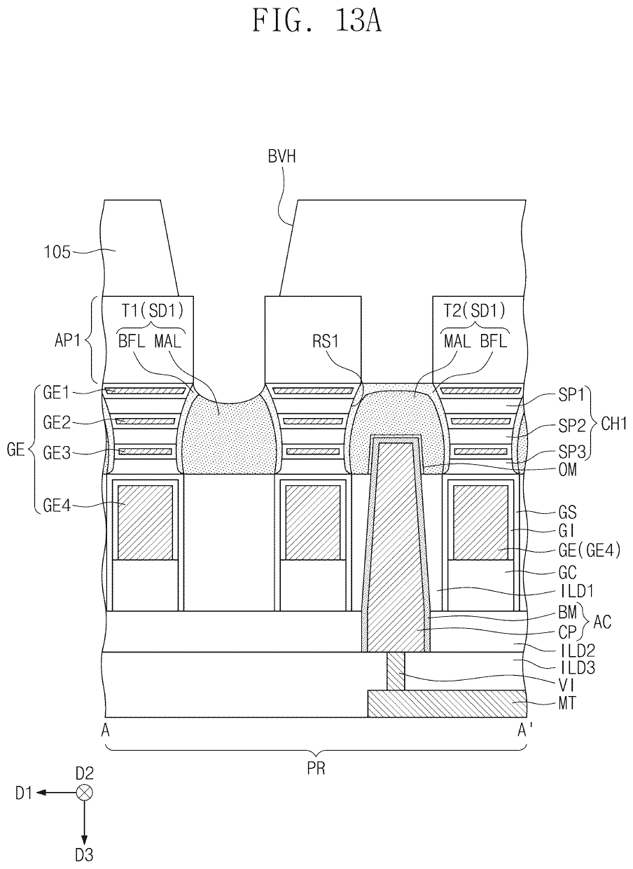

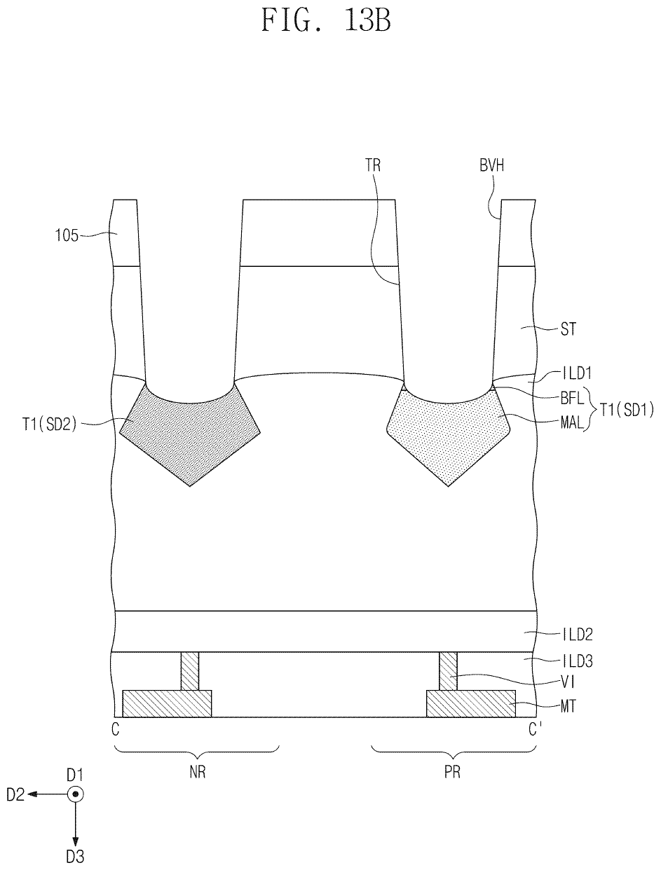

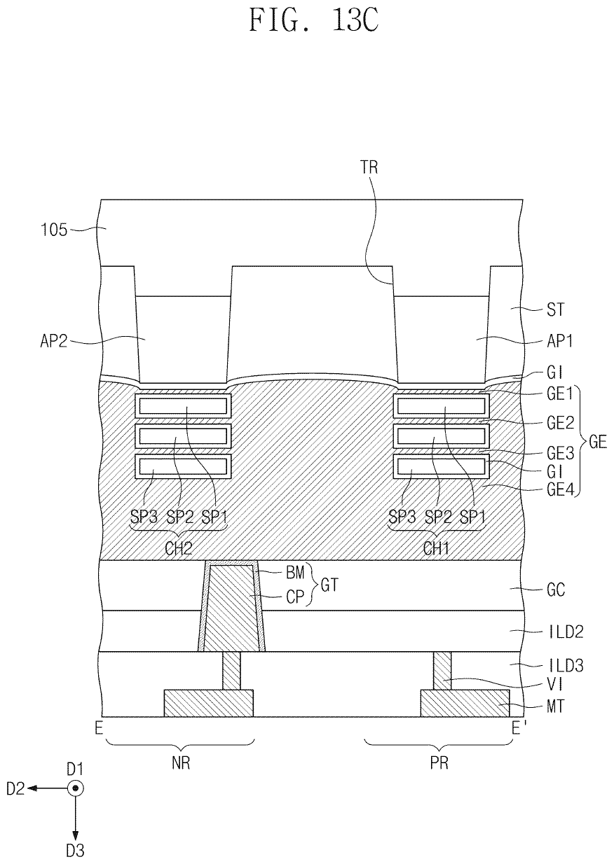

Referring to FIGS. 1 and 13A to 13C, a backside contact hole BVH may be formed on the first pattern T1 to penetrate the substrate 105. Here, the backside contact hole BVH may be formed to further recess an upper portion of the first pattern T1 of each of the first and second source/drain patterns SD1 and SD2. The backside contact hole BVH may not be formed on the first and second active patterns AP1 and AP2 on the gate electrode GE.

In detail, the formation of the backside contact hole BVH may include forming a hard mask pattern on the substrate 105, performing a dry etching process using the hard mask pattern on the substrate 105, and removing the hard mask pattern.

Referring back to FIGS. 1 and 2A to 2E, the backside contact BCS may be formed to fill the backside contact hole BVH. The formation of the backside contact BCS may include forming the backside barrier pattern BBM to conformally cover each of an inner side surface and an inner bottom surface of the backside contact hole BVH and forming the backside conductive pattern BT on the backside barrier pattern BBM to fill a remaining inner space of the backside contact hole BVH. In various example embodiments, the backside conductive pattern BT may be formed through a single process, and in this case, an interface may not be formed in the backside conductive pattern BT. As a result, the backside conductive pattern BT may have a relatively small electric resistance, and this may make it possible to improve the electrical characteristics of the semiconductor device. Next, the power delivery network layer PDN may be formed on the bottom surface of the substrate 105.

In a three-dimensional field effect transistor according to various example embodiments of the inventive concepts, a backside contact may be formed to an optimized depth, and this may make it possible to reduce a parasitic capacitance between a gate electrode and a backside contact. In other words, the backside contact may be formed such that it is not deeply inserted into a source/drain pattern, and thus, the parasitic capacitance may be reduced. Accordingly, a semiconductor device may have improved electrical characteristics.

In a three-dimensional field effect transistor according to various example embodiments of the inventive concepts, an ion implantation process may be performed on a source/drain pattern through a backside surface of substrate, before the forming of a backside contact, and thus, the backside contact may be formed to have an optimized depth. By adjusting the dose and energy conditions for the ion implantation process, it may be possible to selectively activate a desired one of channel layers and consequently to reduce or prevent the backside contact from being deeply formed. Since the backside contact is formed to a desired depth, it may be possible to reduce or prevent the source/drain pattern from being damaged by stress applied thereto. Thus, reliability characteristics of a semiconductor device may be improved.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
a substrate;
source/drain patterns on the substrate, the source/drain patterns comprising a first pattern and a second pattern, the first and second patterns being spaced apart from each other;
a channel pattern between the first pattern and the second pattern, the channel pattern comprising a first semiconductor pattern, a second semiconductor pattern, and a third semiconductor pattern, the first, second, and third semiconductor patterns being stacked to be spaced apart from each other;
an interlayer insulating layer on the source/drain patterns;
an active contact penetrating the interlayer insulating layer and in contact with the second pattern; and
a backside contact penetrating the substrate and in contact with the first pattern,
wherein the first pattern has a first doping concentration, and
the first doping concentration decreases as a vertical distance from the substrate in an upward direction increases, the upward direction being a direction perpendicular to an upper surface of the substrate.

2. The semiconductor device of claim 1, wherein the first pattern comprises
a first region on a side surface of the first semiconductor pattern,
a second region on a side surface of the second semiconductor pattern, and
a third region on a side surface of the third semiconductor pattern,
the first doping concentration of each of the second and third regions ranges from 0 to a first concentration,
the first doping concentration of the first region ranges from a second concentration to a fourth concentration, and
the first doping concentration of the first region is higher than the first doping concentration of each of the second and third regions.

3. The semiconductor device of claim 1, wherein
the second pattern has a second doping concentration, and
the second doping concentration increases as the vertical distance from the substrate in the upward direction increases.

4. The semiconductor device of claim 3, wherein
the second pattern comprises a fourth region on a side surface of the first semiconductor pattern, a fifth region on a side surface of the second semiconductor pattern, and a sixth region on a side surface of the third semiconductor pattern,
the second doping concentration of the fourth region ranges from a first concentration to a second concentration,
the second doping concentration of the fifth region ranges from the first concentration to a third concentration,
the second doping concentration of the sixth region ranges from the third concentration to a fourth concentration, and
the second doping concentration of the sixth region is higher than the second doping concentration of each of the fourth and fifth regions.

5. The semiconductor device of claim 4, wherein
the second doping concentration of the fifth region is higher than the second doping concentration of the fourth region.

6. The semiconductor device of claim 1, wherein
the second pattern has a second doping concentration,
the second doping concentration increases as the vertical distance from the substrate in the upward direction increases, and
the first semiconductor pattern is an electrical path for conduction of charge carriers.

7. The semiconductor device of claim 1, wherein
a bottom surface of the active contact is located at a level higher than a top surface of the backside contact.

8. The semiconductor device of claim 7, wherein
a bottom surface of the active contact is located between top and bottom surfaces of the second semiconductor pattern.

9. The semiconductor device of claim 7, wherein
a top surface of the backside contact is located between top and bottom surfaces of the first semiconductor pattern.

10. The semiconductor device of claim 7, wherein
the first pattern comprises a buffer layer and a main layer on the buffer layer, and
the uppermost surface of the backside contact is in direct contact with the main layer.

11. The semiconductor device of claim 1, further comprising
a gate electrode on the channel pattern, and
an inner spacer between the gate electrode and the first pattern and between the gate electrode and the second pattern.

12. The semiconductor device of claim 1, wherein
the uppermost surface of the backside contact is located at a first level in a direction perpendicular to the substrate,
a bottom surface of the active contact is located at a second level in a direction perpendicular to the substrate, and
each of the first and second levels is located between top and bottom surfaces of the first semiconductor pattern.

13. The semiconductor device of claim 12, wherein
the first level is equal to the second level.

14. A semiconductor device, comprising:
a substrate;
a power delivery network layer on a bottom surface of the substrate;
source/drain patterns on the substrate; and
backside contacts provided to penetrate the substrate and to electrically connect each of the source/drain patterns to the power delivery network layer,
wherein the backside contacts comprise a first backside contact and a second backside contact, the first and second backside contacts being spaced apart from each other,
each of the first and second backside contacts comprises a first portion and a second portion on the first portion,
wherein a width of the first portion decreases as a vertical distance from the substrate in an upward direction increases, the upward direction being a direction perpendicular to an upper surface of the substrate, and
as the vertical distance from the substrate in the upward direction increases, a width of the second portion is maintained at a constant value and then decreased.

15. The semiconductor device of claim 14, wherein the source/drain patterns comprises
a buffer layer and a main layer on the buffer layer, and
the uppermost surface of each of the first and second backside contacts is in direct contact with the main layer.

16. The semiconductor device of claim 14, wherein
the uppermost surface of the first backside contact is located at a level that is equal to the uppermost surface of the second backside contact, in a direction perpendicular to the upper surface of the substrate.

17. The semiconductor device of claim 14, further comprising
active patterns on the substrate,
wherein the width of the second portion is maintained at a constant value between the active patterns and then is decreased at a point in contact with the source/drain pattern.

18. A semiconductor device, comprising:
a substrate including an insulating layer and an active pattern;
a power delivery network layer on a bottom surface of the insulating layer;
source/drain patterns on the insulating layer, the source/drain patterns comprising a first pattern and a second pattern, the first and second pattern being spaced apart from each other;
a channel pattern on a side surface of the source/drain pattern, the channel pattern comprising a plurality of semiconductor patterns, the plurality of semiconductor patterns being stacked to be spaced apart from each other and include a first semiconductor pattern, a second semiconductor pattern, and a third semiconductor pattern;
a gate electrode between the semiconductor patterns, the gate electrode comprising a first inner electrode, a second inner electrode, and a third inner electrode, the first, second and third inner electrodes being interposed between adjacent ones of the semiconductor patterns, and an outer electrode on the uppermost one of the semiconductor patterns;
a gate insulating pattern on the gate electrode;
a gate capping pattern on a top surface of the outer electrode;
a first interlayer insulating layer on the source/drain patterns;
a second interlayer insulating layer on the first interlayer insulating layer and the gate capping pattern;
a third interlayer insulating layer on the second interlayer insulating layer, metal patterns and vias are within the third interlayer insulating layer;
an active contact penetrating the first and second interlayer insulating layers and electrically connecting the second pattern of the source/drain pattern to the metal pattern; and
a backside contact penetrating the insulating layer of the substrate and electrically connecting the first pattern of the source/drain pattern to the power delivery network layer,
wherein the first pattern has a first doping concentration,
the second pattern has a second doping concentration, and
the first doping concentration of a portion of the first pattern being adjacent to a side surface of the first semiconductor pattern, is higher than the second doping concentration of a portion of the second pattern being adjacent to the side surface of the first semiconductor pattern.

19. The semiconductor device of claim 18, wherein
the first doping concentration of the portion of the first pattern ranges from 1.0×10²⁰ atom/cm³ to 5.0×10²² atom/cm³, and
the second doping concentration of the portion of the second pattern ranges from 1.0×10¹⁸ atom/cm³ to 1.0×10¹⁹ atom/cm³.

20. The semiconductor device of claim 18, wherein
one of the first to third semiconductor patterns is an electrical path for conduction of charge carriers.
